(19) United States
(12) Patent Application Publication
(10) Pub. No.: US 2011/0108681 A1
(43) Pub. Date: May 12, 2011

(54) METHOD AND APPARATUS FOR FACILITATING CABLE TERMINATIONS OF RACK MOUNTED EQUIPMENT

(76) Inventor: David Andrew McKenzie-McHarg, New South Wales (AU)

(21) Appl. No.: 13/002,323

(22) PCT Filed: Jul. 27, 2009
(86) PCT No.: PCT/AU09/00952

§ 371 Date: Dec. 31, 2010

(30) Foreign Application Priority Data
Jul. 28, 2008 (AU) 2008903831

(51) Int. Cl. H05K 7/14; H05K 13/00; F16L 3/08

(52) U.S. Cl. 248/70; 29/592.1; 248/74.1

(57) ABSTRACT

A method and apparatus for facilitating the termination of cables to equipment mounted inside equipment racks or cabinets comprising of one or more cable termination equipment such as patch panels, cable termination strips and terminal blocks, and printed circuit boards fitted with cable termination blocks or fibre optic termination equipment. The method and apparatus of this invention make it possible to terminate cables to rack mounted equipment with ease and comfort.

### INTRODUCTION

This invention relates to a method and apparatus for facilitating the termination of cables inside equipment racks or cabinets comprising of one or more cable termination equipment such as patch panels, cable termination strips and terminal blocks, and printed circuit boards fitted with cable termination blocks or fibre optic termination equipment. The method and apparatus of this invention make it possible to terminate cables within equipment racks with ease and comfort.

A number of terms and expressions are used herein and their meanings in relation to this invention are given below.

Equipment rack: Any structure such as a rack, cabinet, frame or enclosure designed to house equipment at which cables are terminated. The cables may comprise of one or more electrical conductors or they may be fibre based.

Patch panel: Rack mounted termination module at which cables are terminated.

### BACKGROUND

The use of cable termination equipment within equipment racks is widespread, especially in cabling systems for data, communications, audio, video, electronic and electrical control systems. These equipment racks are usually floor or wall mounted, and incorporate various types of cable termination equipment mounted in their final position at various heights within the equipment racks. The racks themselves are also of limited width and, for all intents and purposes, are considered to be confined spaces in relation to the physical size of the human body. Thus, this standard and common arrangement makes it difficult for any technician to undertake cable termination work at equipment racks, work which has to be undertaken in confined spaces.

In addition to the difficulty in carrying out cable termination work in the confined spaces of equipment racks, cable terminations within equipment racks are made more difficult in the lower portions of the equipment racks as the technician usually has to assume a position close to the floor which is not comfortable. Similarly, cable terminations to rack mounted equipment that are located high above the floor are also problematic in that the technician must then work uncomfortably from ladders or other supporting means, work which sometimes has to be carried out for extended periods of time.

It is therefore realised, from the above descriptions, that the known method of terminating cables and equipment in situ within the confined spaces of equipment racks, and/or at uncomfortably low or high positions within the equipment racks, is difficult and disadvantageous.

### OBJECT OF THE INVENTION

It is therefore the object of this invention to overcome the difficulty and disadvantage of prior art equipment racks in relation to cable terminations at rack mounted equipment. This object of the invention is achieved by way of the new method and apparatus of this invention that enables the termination of cables for rack mounted equipment to be carried out at a comfortable height and position outside of, but in close proximity to, the equipment rack.

### BRIEF SUMMARY OF THE INVENTION

This invention in one aspect resides broadly in a method for facilitating cable terminations for rack mounted equipment, the method including:

removing the rack mounted equipment at which the cables are to be terminated from the equipment rack;

installing the rack mounted equipment to be terminated at a suitable height and in an accessible location on or within a holding device located outside of the equipment rack;

providing all cables to be terminated at rack mounted equipment with sufficient slack for extension outside of the equipment rack;

extending the cables to be terminated outside of the equipment rack using the available slack cabling provided;

terminating the cables at the equipment installed on or within the holding device outside of the equipment rack;

removing the already terminated equipment from the holding device outside of the equipment rack;

re-installing the already terminated equipment in its required position within the equipment rack, and

dressing and making good of any slack cabling within the equipment rack.

The method may also include dressing and making good of any slack cabling partly or entirely outside of the equipment rack depending on whether space is available within the equipment rack for partly or fully accommodating any slack cabling.

In another aspect the invention resides in the provision of an apparatus suitable for securing and holding rack mounted termination equipment at a suitable height, location and position outside an equipment rack whilst cabling extended from the equipment rack is being terminated at the termination equipment.

It is to be noted that the apparatus of this invention can take various forms depending on the size of the equipment to be terminated, the appropriate method to be used for holding and securing the rack mounted termination equipment on or within the apparatus of this invention, and the height and position at which it would be most advantageous, easy and comfortable to undertake cable termination work outside of the equipment rack. Thus, and without departing from the intent of this invention, it is to be understood that the apparatus of this invention could include any of the following features alone or in any combination with each other:

mechanical holding and securing means such as screws, clamps, snap-fit securing devices and the like for securing rack mounted termination equipment on or within the apparatus of this invention;

height adjusting means for positioning the rack mounted termination equipment at an appropriate height for ensuring that cable termination is easy and comfortable;

mechanical folding means so that the apparatus of this invention can be folded in an appropriate compact form during transportation and storage, and

relocation means, such as wheels and casters, for facilitating the relocation of the apparatus of this invention to any suitable location relative to an equipment rack in which cables are required to be terminated.

Although the method of this invention for facilitating cable terminations of rack mounted equipment is self explanatory, the apparatus of this invention is best explained by referring to the following embodiment of the invention. However, the embodiment described in the following subsections of this specification, and illustrated by the accompanying drawings, is merely illustrative of how the invention might be put into effect and is not to be understood as being limiting on the invention. It is also to be understood that the invention can be put into effect in a number of ways and that the embodiment described is only an example of the number of forms the invention can take.

### EMBODIMENT OF THE INVENTION

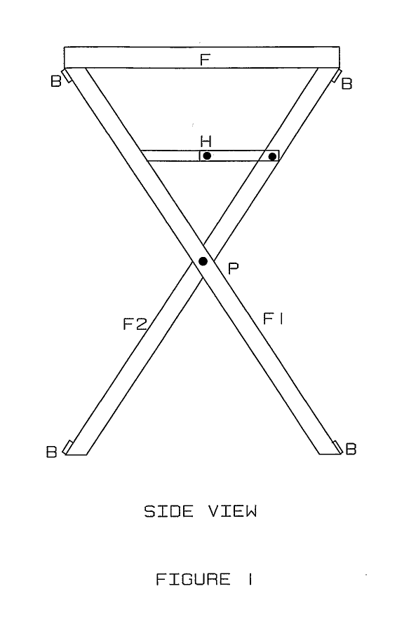

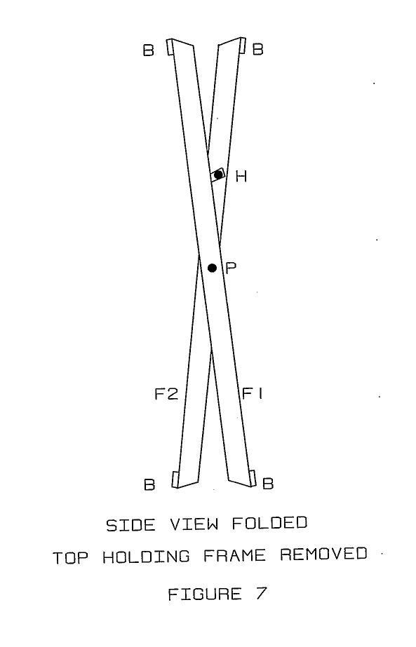

An embodiment of the invention is the apparatus described by FIG. 1 through to FIG. 7 inclusive. The drawings provide details of an apparatus used to hold and secure one or more patch panels temporarily removed from an equipment rack. Descriptions of the drawings and how the apparatus is used are as follows.

FIG. 1 is a side view of an embodiment of this invention shown fully open. The apparatus comprises of two metal frames F1 and F2 suitably braced by metal braces B at the top and bottom of the frames. The outer frame F1 is made wide enough to accommodate the inner frame F2 of smaller width. The inner and outer frames are pivotally connected at pivots P, with flat metal hinge H acting as a stop when the apparatus is a fully open position.

The side view of FIG. 1 also shows a detachable metal holding frame F at the top of the apparatus, frame which is used for holding any rack mounted termination equipment at which cables are to be terminated. The detachable frame F is supported by frames F1 and F2 which also serve as legs for the apparatus.

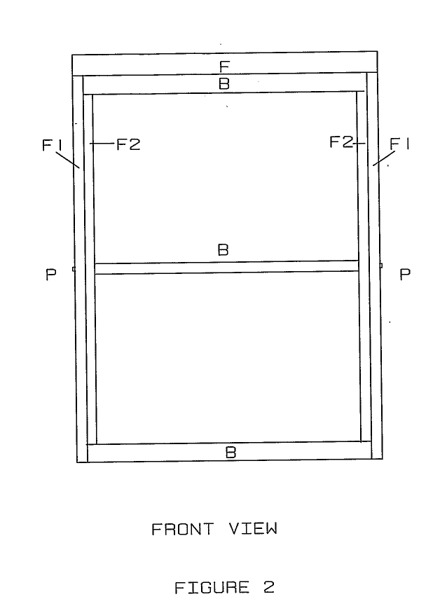

FIG. 2 is a front view of the embodiment of the invention showing the relative positions of inner frame F2, outer frame F1, metal braces B at top and bottom of the frames, pivots P and the detachable frame F at the top. An additional metal brace B is also provided to the inner frame for added rigidity.

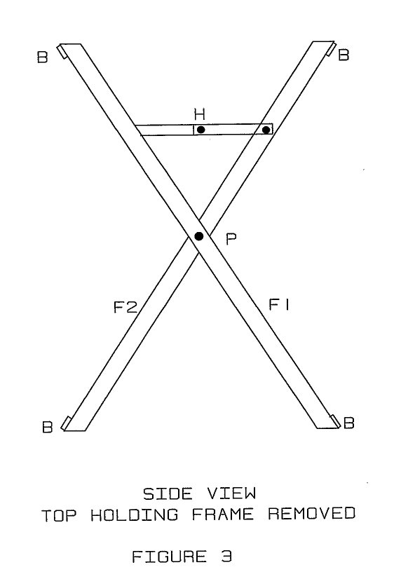

The description for FIG. 3 is the same as that for FIG. 1 except that FIG. 3 does not show the top detachable metal holding frame F which has been detached.

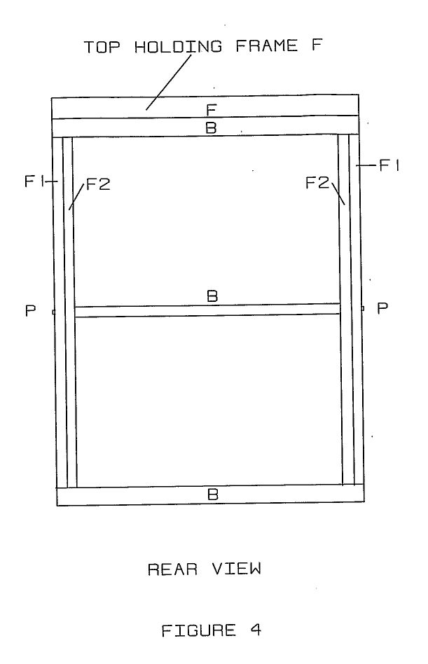

The description for FIG. 4 is the same as that for FIG. 2 except that FIG. 4 shows the relative positions of detachable holding frame F, inner frame F2, outer frame F1, braces B and pivots P viewed from the rear of the apparatus.

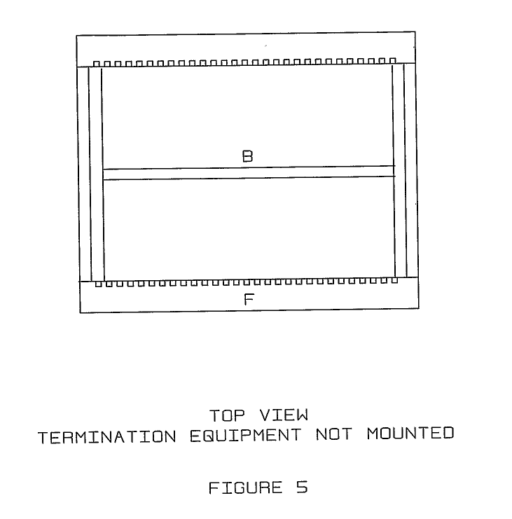

FIG. 5 is a top view of the embodiment of the invention and shows a holding frame F designed to hold and secure one or more patch panels. The patch panels are secured in position on the holding frame F using nuts and bolts. The drawing also shows a metal brace B of the inner frame F2 of the apparatus (refer to FIG. 2).

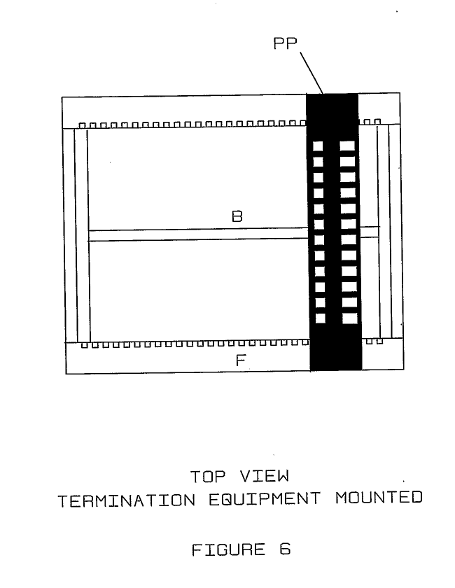

The description for FIG. 6 is the same as for FIG. 5 except that FIG. 6 shows a top view of the embodiment of the invention with a patch panel PP mounted on the holding frame F using nuts and bolts.

FIG. 7 is a side view of the embodiment of the invention with the holding frame F detached and the apparatus in a folded position. FIG. 7 also shows the relative positions of inner frame F2, outer frame F1, braces B at the top and bottom of the frames, pivot P and flat metal hinge H.

The open and complete apparatus (FIG. 1) of this invention is designed to have dimensions that result in the termination equipment held in holding frame F being at a height at which cable termination is easy and comfortable.

According to this invention, the apparatus illustrated by drawings of FIG. 1 through to FIG. 7 is used by a technician to terminate rack mounted patch panels by:

removing the patch panels PP at which the cables are to be terminated from the equipment rack;

installing the patch panels PP to be terminated on or within the holding frame F of the apparatus of this invention so that the patch panels are at a height at which cable termination is easy and comfortable;

providing all cables to be terminated at the patch panels PP with sufficient slack for extension outside of the equipment rack;

extending the cables to be terminated outside of the equipment rack using the available slack cabling provided;

terminating the cables at the patch panels PP installed on or within the holding device outside of the equipment rack;

removing the already terminated patch panels PP from the holding device outside of the equipment rack;

re-installing the already terminated patch panels PP in their required position within the equipment rack, and

dressing and making good of any slack cabling in an appropriate location within or outside of the equipment rack.

Patch panels can be terminated one at a time or in batches.

It can be seen from the above description that the method and apparatus of this invention is advantageous in that it does not require the technician to work within a confined space in equipment racks. Furthermore the technician also does not need to assume awkward or uncomfortable positions whilst terminating cables. It is also obvious that in some cases the termination equipment to be rack mounted will be supplied separately from the equipment rack, in which case the initial step comprising of the removal of the termination equipment from the equipment rack is not necessary.

The above description only describes one embodiment of the invention which may take various forms without departing from the intent of the invention. Thus the holding device can be a free standing item as per FIG. 1 or it can comprise of adapters and a frame to be attached to an outer side of an equipment rack. It can also been seen that the method and apparatus of this invention is not limited to the termination of patch panels but can easily be adapted to suit a variety of termination devices such as cable termination strips and terminal blocks and printed circuit boards fitted with cable termination blocks and fibre optic termination equipment.

1. A method for facilitating cable terminations of rack mounted equipment, the method including:
removing the rack mounted equipment at which the cables are to be terminated from the equipment rack;
installing the rack mounted equipment to be terminated at a suitable height and in an accessible location on or within a holding device located outside of the equipment rack;
providing all cables to be terminated at rack mounted equipment with sufficient slack for extension outside of the equipment rack;
extending the cables to be terminated outside of the equipment rack using the available slack cabling provided;
terminating the cables at the equipment installed on or within the holding device outside of the equipment rack;
removing the already terminated equipment from the holding device outside of the equipment rack;
re-installing the already terminated equipment in its required position within the equipment rack, and
dressing and making good of any slack cabling.

2. A method as claimed in claim 1 wherein the dressing and making good of any slack cabling is entirely within the equipment rack.

3. A method as claimed in claim 1 wherein the dressing and making good of any slack cabling is entirely outside of the equipment rack.

4. A method as claimed in claim 1 wherein the dressing and making good of any slack cabling is partly within the equipment rack and partly outside the equipment rack.

5. An apparatus suitable for securing and holding rack mounted termination equipment at a suitable height, location and position outside an equipment rack whilst cabling extended from the equipment rack is being terminated at the termination equipment, the apparatus including mechanical holding and securing means such as screws, clamps, snap-fit securing devices and the like for securing rack mounted termination equipment on or within the apparatus.

6. An apparatus as claimed in claim 5 wherein the apparatus further comprises of height adjusting means for positioning the rack mounted termination equipment at an appropriate height for ensuring that cable termination is easy and comfortable.

7. An apparatus as claimed in claim 5 wherein the apparatus further comprises of mechanical folding means so that the apparatus can be folded in an appropriate compact form during transportation and storage.

8. An apparatus as claimed in claim 5 wherein the apparatus further comprises of relocation means, such as wheels and castors, for facilitating the relocation of the apparatus to any suitable location.

9. An apparatus as claimed in claim 5 wherein the apparatus is fixed and non-demountable.

10. An apparatus as claimed in claim 5 wherein the apparatus is demountable.

11. An apparatus as claimed in claim 5 wherein the apparatus is free standing.

12. An apparatus as claimed in claim 5 wherein the apparatus is fixed externally to the equipment rack
